(19) United States
(12) Patent Application Publication
(10) Pub. No.: US 2011/0292653 A1
(43) Pub. Date: Dec. 1, 2011

(54) LED lamp, method for manufacturing and LED lamp and bulb therefor

(75) Inventors: Markus Hofmann, Bad Abbach (DE); Fabian Reingruber, Munich (DE)

(73) Assignee: OSRAM GESELLSCHAFT MIT BESCHRAENKTER HAFTUNG, Muenchen (DE)

(21) Appl. No.: 13/115,153

(22) Filed: May 25, 2011

(30) Foreign Application Priority Data
May 31, 2010 (DE) 10 2010 029 515.9

(51) Int. Cl. F21V 11/00; H01L 21/00; F21V 29/00

(52) U.S. Cl. 362/235; 29/25.01

(57) ABSTRACT

In various embodiments, a semiconductor lamp may include at least one semiconductor light source; a heat sink for cooling at least the at least one semiconductor light source; and a diffuser fixed to the heat sink; wherein the heat sink has at least one receptacle space; wherein the receptacle space is filled with solid filling compound; and at least one part of an edge of the diffuser is dipped into the filling compound in a positively locking manner.

The invention relates to a semiconductor lamp including at least one semiconductor light source, a heat sink for cooling at least the at least one semiconductor light source, and a diffuser fixed to the heat sink. The invention furthermore relates to a method for manufacturing a bulb for the semiconductor lamp, wherein the bulb is a glass bulb. The invention additionally relates to a method for, manufacturing a semiconductor lamp.

One problem in LED lamps is the dissipation of heat from the light emitting diodes (LEDs). In the case of LED retrofit lamps, which replace a conventional lamp, such as e.g. an incandescent lamp, and for this purpose are intended to be similar to the conventional lamp at least externally (e.g. with regard to a size and form of the outer contour), part of the heat can also be dissipated via a diffuser, e.g. a bulb. The diffuser is placed over the LEDs for the purpose of scattering light and often consists of glass, in particular milk glass. Since glass has a good thermal conductivity and can easily be brought to a spherical form, it is very well suited as diffuser material. The glass, for mounting purposes, is applied to a typically metallic heat sink of the LED lamp, said heat sink usually being created in an injection molding method.

In order to avoid a glass fracture, e.g. in the case of temperature fluctuations on account of the different thermal expansion of glass and metal, direct contact between the glass and the metallic heat sink by means of a conformal connection should be avoided. Moreover, in the case of direct metal-glass contact, cracking can occur in the glass. Therefore, the diffuser and the heat sink are often adhesively bonded to one another. What is disadvantageous about the adhesive bonding, however, is that it is subject to continual temperature fluctuations, and can then become detached over time, such that the glass bulb drops off.

The object of the present invention is to avoid the disadvantages of the prior art and, in particular, to provide a failure-unsusceptible and durable possibility for connecting a diffuser to a heat sink of an LED lamp.

This object is achieved in accordance with the features of the independent claims. Preferred embodiments can be gathered from the dependent claims, in particular.

Said object is achieved by means of a semiconductor lamp, including
at least one semiconductor light source,
a heat sink for cooling at least the at least one semiconductor light source, and
a diffuser fixed to the heat sink,
wherein
the heat sink has at least one receptacle space,
the receptacle space is filled with solid (not liquid (low-viscosity) or granular) filling compound, and
at least one part of an edge of the diffuser is dipped into the filling compound in a positively locking manner.

This semiconductor lamp has the advantage that the bulb is no longer directly in contact with the heat sink, but rather is in contact via the filling compound. As a result, it is possible to avoid cracking in the bulb and also a bulb fracture. The filling compound can, e.g. with regard to its elastic compliance, be correspondingly coordinated with the form and constitution of the bulb. As a result of the positively locking dipping process, the diffuser, in particular bulb, can be effectively prevented from falling out, even in the case of a non-adhering filling compound.

Preferably, the at least one semiconductor light source includes at least one light emitting diode. In the case where a plurality of light emitting diodes are present, they can emit light in the same color or in different colors. A color can be monochrome (e.g. red, green, blue, etc.) or multichrome (e.g. white). The light emitted by the at least one light emitting diode can also be an infrared light (IR-LED) or an ultraviolet light (UV-LED). A plurality of light emitting diodes can generate a mixed light; e.g. a white mixed light. The at least one light emitting diode can contain at least one wavelength-converting phosphor (conversion LED). The at least one light-emitting diode can be present in the form of at least one individually housed light emitting diode or in the form of at least one LED chip. A plurality of LED chips can be mounted on a common substrate (“Submount”). The at least one light emitting diode can be equipped with at least one dedicated and/or common optical unit for beam guiding, e.g. at least one Fresnel lens, collimator, and so on. Instead of or in addition to inorganic light emitting diodes, e.g. based on InGaN or AlInGaP, organic LEDs (OLEDs, e.g. polymer OLEDs) can generally be used as well. Alternatively, the at least one semiconductor light source can include e.g. at least one diode laser.

In one configuration, a part of the filling compound is covered by a printed circuit board, wherein the printed circuit board is populated with at least one semiconductor light source. As a result, without additional components, it is possible to prevent the filling compound from falling out of the at least one receptacle.

In an alternative configuration, a part of the filling compound is covered by a holding ring, wherein the holding ring presses a printed circuit board, which is populated with at least one semiconductor light source, marginally or at an edge region onto the heat sink. The holding ring can therefore both hold the printed circuit board on the heat sink and prevent the filling compound from falling out of the receptacle.

The two configurations in which at least one receptacle space is covered are advantageous particularly for a heat sink produced by means of an injection molding technique, since said heat sink advantageously produces no lateral recesses or projections in the receptacle space which could hold the filling compound by a positively locking fit in the receptacle.

In an alternative configuration, at least one receptacle has a lateral recess and/or projection. The filling compound can thus be held by a positively locking fit in the receptacle. The recess and/or projection can be produced e.g. by material-removing processing of the at least one receptacle, e.g. by means of relief milling, particularly in the case of a molded, in particular an injection-molded, heat sink. A recess and/or a projection projecting into the receptacle space can also be realized, in the case of a bent sheet-metal heat sink, by means of corresponding bending without subsequent material removal.

In one configuration, the at least one semiconductor light source is arranged at a front side of the heat sink, and the at least one receptacle space is embodied as at least one depression introduced in the front side of the heat sink. As a result, the diffuser can be placed by a simple placement movement (over the filling compound) onto the heat sink and cover the semiconductor light source(s). Moreover, the heat sink can be configured in a particularly simple manner at its front side.

In one specific configuration, the at least one semiconductor light source is arranged on a printed circuit board, and the at least one receptacle space is embodied as a ring-shaped depression laterally surrounding the printed circuit board. A substantially complete covering of the semiconductor light source(s) and a semiconductor lamp that is simple to produce and assemble are provided as a result.

In one configuration, moreover, at least one spacer composed of an elastic material for supporting the diffuser is present at the front side of the heat sink. It can thus be ensured that the diffuser does not come into contact with the heat sink outside the receptacle space. The spacer can be a sealing ring, for example, which is introduced into a matching ring groove in the heat sink, particularly if the ring groove is introduced into the front side of the heat sink. The ring groove can run, in particular, laterally outside the at least one receptacle space.

In another configuration,
the semiconductor lamp is an incandescent lamp retrofit lamp,
the diffuser is present in the form of a bulb, the edge of which has a ring-shaped bead and
the bulb dips into the filling compound at least with its ring-shaped bead.

The ring-shaped bead makes it possible to manufacture a positively locking connection to the filling compound in a simple manner.

In the case where such an incandescent lamp retrofit lamp is present, the at least one receptacle space is preferably configured as a ring-shaped receptacle space or ring groove for the purpose of particularly stable fixing.

Generally, the receptacle space can also be configured such that it does not extend circumferentially, e.g. with a plurality of sections arranged in an angular-sector-shaped manner or differently. The diffuser can then have a plurality of projections, in particular downwardly directed projections, which can be dipped into at least one part of the plurality of receptacle spaces. This can provide a particularly high design flexibility.

For a particularly fixed linking of the diffuser to the filling compound and/or a particularly fixed linking of the heat sink to the filling compound, in one configuration, the filling compound is an adhesive. For the purpose of simple assembly, the adhesive can be, in particular, a curing adhesive or adhesive substance.

In another configuration, the filling compound is or includes silicone.

The object is also achieved by means of a method for producing a bulb for the semiconductor lamp as described above, wherein the bulb is a glass bulb, and the glass bulb in a hot state is placed by its edge onto a support until the ring-shaped bead is formed (as a result of the inherent weight of the glass bulb). In the case of a plastic bulb, the bead can be concomitantly shaped (e.g. directly during an injection molding process).

The object is also achieved by means of a method for manufacturing the semiconductor lamp including at least the following steps:
filling a receptacle space of a heat sink of the semiconductor lamp with a liquid or pasty filling compound;
dipping a diffuser into the filling compound;
curing the filling compound.

The (initially) liquid filling compound can also be a pasty or viscous filling compound. The filling compound can be pressed into the receptacle space, e.g. silicone.

In order to avoid direct contact with the heat sink, the diffuser is dipped into the filling compound only to an extent such that it is completely surrounded by the filing compound (and does not make contact with a wall of the receptacle space).

In the following figures, the invention is described in greater detail schematically on the basis of exemplary embodiments. In this case, for the sake of clarity, identical or identically acting elements may be provided with identical reference symbols.

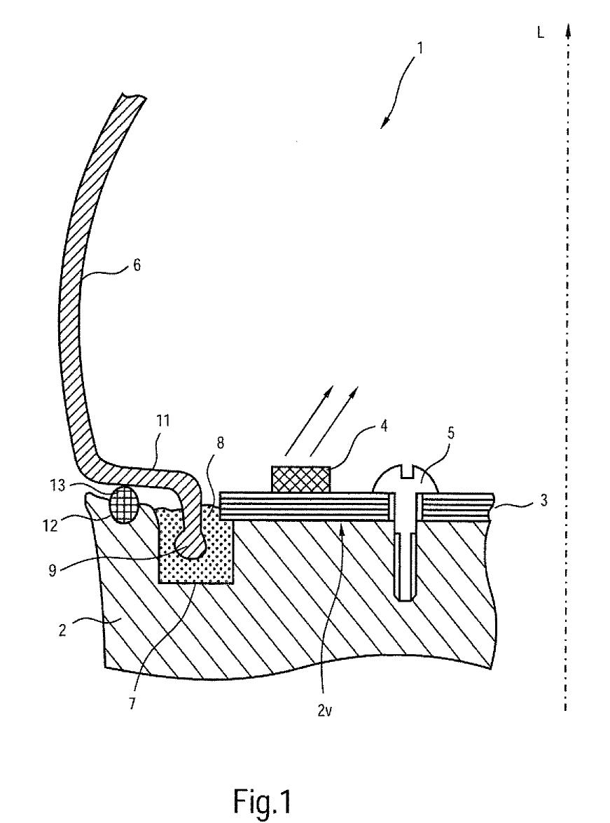

FIG. 1 shows, as a sectional illustration in side view, an excerpt from a semiconductor lamp in accordance with a first embodiment; and

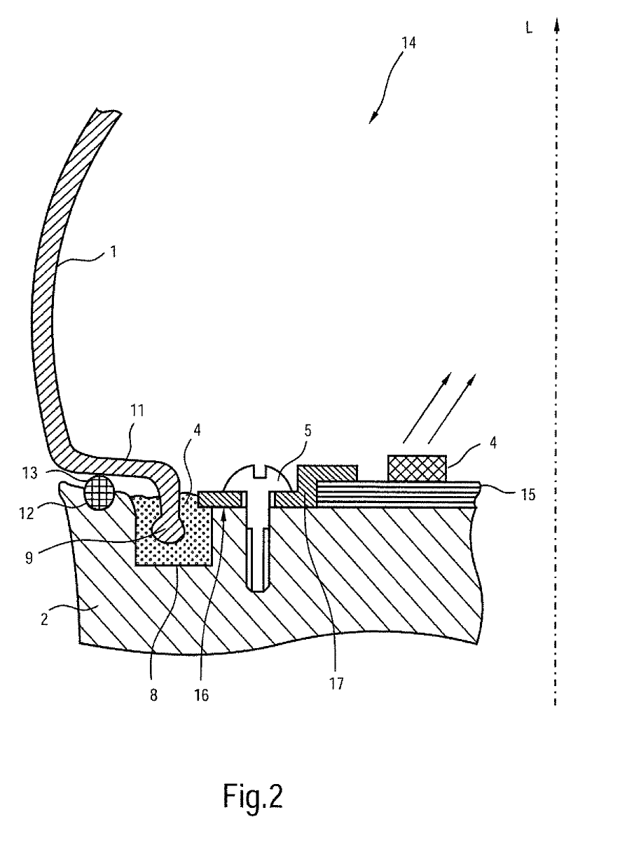

FIG. 2 shows, as a sectional illustration in side view, an excerpt from a semiconductor lamp in accordance with a second embodiment.

FIG. 1 shows, as a sectional illustration in side view, an excerpt from a semiconductor lamp 1 in accordance with a first embodiment. The semiconductor lamp 1 is configured as an incandescent lamp retrofit lamp and, for this purpose, is configured at least approximately symmetrically with respect to a longitudinal axis L. At its back or rear end, the semiconductor lamp 1 has a base (not illustrated) for making contact with a mount and emits substantially toward the front (into a front half-space). In this case, the longitudinal axis L is oriented from the back toward the front.

The semiconductor lamp 1 includes a metallic heat sink (e.g. composed of or including aluminum), on the front side 2v of which a substantially circular printed circuit board 3 bears centrally. On its front side, the printed circuit board 3 is populated with at least one light emitting diode (LED) 4 (e.g. with a plurality of white light emitting diodes 4 arranged angularly symmetrically about the longitudinal axis L) and bears with its rear side areally on the heat sink 2. Thus, waste heat generated by the at least one light emitting diode 4 can be effectively transferred to the heat sink via the printed circuit board 3 and can be emitted from said heat sink to the surroundings. For the purpose of fixing the printed circuit board 3, the latter can be screwed to the heat sink 2 e.g. by means of at least one screw 5.

For the purpose of fixing a diffuser in the form of a glass bulb 6, which is shaped approximately in a pear-shaped fashion, to the heat sink 2, the heat sink 2 has, at its front side 2v, a circumferential ring groove 7, which is filled with a filling compound 8 in the form of a cured adhesive. The filling compound 8 can be, in particular, a material that is elastic in the cured state, e.g. a plastic.

A lower edge of the glass bulb 6 is dipped into the filling compound 8, said edge being embodied as a ring-shaped bead 9. In this case, the glass bulb 6 does not touch the heat sink 2, but rather is only in contact with the filling compound 8. The ring-shaped bead 9 may have been produced for example by the glass bulb 6 in a hot state having been placed by its (lower, open) edge onto a support until the ring-shaped bead 9 is formed. The ring-shaped bead 9 brings about a positively locking connection to the filling compound 8, such that the glass bulb 6 cannot become detached from the filling compound 8 even when an adhesive effect has been lost. Moreover, use of a non-adhering filling compound 8 is made possible in this way.

In order to prevent the filling compound 8 from becoming detached from the heat sink (since no lateral recesses or projections are present in the ring groove 7), the printed circuit board 3 extends laterally or radially as far as partly over the ring groove 7 and the filling compound 8, such that it partly covers the filling compound 8, but is still at a distance from the glass bulb 6. The filling compound 8 is thus held by a positively locking fit with the printed circuit board 3 in the ring groove 7. In other words, the printed circuit board 3 projects beyond its bearing area laterally delimited by the ring groove 7 and thereby partly covers the ring groove 7.

Proceeding from its edge or ring-shaped bead 9, the glass bulb 6 in profile firstly runs upward, then bends away approximately at right angles toward the outside (here: toward the left) until it reaches the edge of the heat sink, and then bends away upward again in the other direction, to be precise not completely at right angles. As a result, the glass bulb 6 is adjacent to the heat sink 2 in an approximately flush fashion at the outer side or outer contour of the semiconductor lamp 1, thus resulting in a substantially continuous transition between the heat sink 2 and the glass bulb 6, as viewed from outside. This results in an (in profile) section 11 or ring-shaped region of the glass bulb 6 which runs parallel to the front side 2v of the heat sink 2.

In order to prevent a situation in which the glass bulb 6, upon being dipped into the filling compound 8, is placed directly on the heat sink 2 (with the ring-shaped bead 9 in the ring groove 7 or with the section 11 on the front side 2v), the heat sink 2 has at its top side a second ring groove 12, which surrounds the ring groove 7 on the outer side. A spacer 13 in the form of an O-ring projecting upward beyond the front side 2v is introduced in the second ring groove 12, and ensures a perpendicular or vertical distance between the glass bulb 6 and the heat sink 2.

In order to produce the semiconductor lamp 1, firstly the ring groove 7 is filled with the filling compound 8 and then the glass bulb 6 is dipped by its ring-shaped bead 9 into the filling compound 8. Afterward, the filling compound 8 is cured (actively cured, e.g. by means of heat or UV treatment) or left to cure (e.g. by curing in air). A step of placing the printed circuit board 3 on the heat sink 2 in such a way that the printed circuit board 3 partly covers the filling compound 8 can be carried out before or after the curing.

FIG. 2 shows, in an illustration analogous to FIG. 1, a semiconductor lamp 14 in accordance with a second embodiment.

The semiconductor lamp 14 is constructed similarly to the semiconductor lamp 1, except that the printed circuit board 15 now does not reach as far as the ring groove 7 and, at its circumferential region 16 or outer edge, is surrounded by a holding ring 17 and can also be held down by the latter. The holding ring 17 can be fixed to the heat sink 2 by the screw 5. The holding ring 17 projects over the ring groove 7 and serves for retaining the filling compound 8.

It goes without saying that the present invention is not restricted to the exemplary embodiments shown.

Thus, the ring groove 7, besides being covered by the printed circuit board 3 or the holding ring 17, can generally be covered by any other suitable element, e.g. at least one screw head, at least one lug, etc.

### LIST OF REFERENCE SYMBOLS

1 Semiconductor lamp
2 Heat sink
2v Front side
3 Printed circuit board
4 Light emitting diode
5 Screw
6 Glass bulb
7 Ring groove
8 Filling compound
9 Ring-shaped bead
11 Section of the glass bulb
12 Second ring groove
13 Spacer
14 Semiconductor lamp
15 Printed circuit board
16 Circumferential region
17 Holding ring
L Longitudinal axis

1. A semiconductor lamp, comprising:
at least one semiconductor light source;
a heat sink for cooling at least the at least one semiconductor light source; and
a diffuser fixed to the heat sink;
wherein
the heat sink has at least one receptacle space;
the receptacle space is filled with solid filling compound; and
at least one part of an edge of the diffuser is dipped into the filling compound in a positively locking manner.

2. The semiconductor lamp as claimed in claim 1,
wherein a part of the filling compound is covered by a printed circuit board,
wherein the printed circuit board is populated with at least one semiconductor light source.

3. The semiconductor lamp as claimed in claim 1,
wherein a part of the filling compound is covered by a holding ring,
wherein the holding ring presses a printed circuit board, which is populated with at least one semiconductor light source, marginally onto the heat sink.

4. The semiconductor lamp as claimed in claim 1,
wherein the at least one semiconductor light source is arranged at a front side of the heat sink, and the at least one receptacle space is embodied as at least one depression introduced in the front side of the heat sink.

5. The semiconductor lamp as claimed in claim 4,
wherein the at least one semiconductor light source is arranged on a printed circuit board, and the at least one receptacle space is embodied as a ring-shaped depression laterally surrounding the printed circuit board.

6. The semiconductor lamp as claimed in claim 4, wherein at least one spacer composed of an elastic material for supporting the diffuser is present at the front side of the heat sink.

7. The semiconductor lamp as claimed in claim 1, wherein
the semiconductor lamp is an incandescent lamp retrofit lamp,
the diffuser is present in the form of a bulb, the edge of which has a ring-shaped bead, and
the diffuser dips into the filling compound at least with its ring-shaped bead.

8. The semiconductor lamp as claimed in claim 1,
wherein the filling compound is an adhesive.

9. The semiconductor lamp as claimed in claim 1,
wherein the filling compound is silicone.

10. A method for manufacturing a bulb for a semiconductor lamp, the semiconductor lamp comprising:
at least one semiconductor light source;
a heat sink for cooling at least the at least one semiconductor light source; and
a diffuser fixed to the heat sink;
wherein
the heat sink has at least one receptacle space;
the receptacle space is filled with solid filling compound; and
at least one part of an edge of the diffuser is dipped into the filling compound in a positively locking manner;
the semiconductor lamp is an incandescent lamp retrofit lamp,
the diffuser is present in the form of a bulb, the edge of which has a ring-shaped bead, and
the diffuser dips into the filling compound at least with its ring-shaped bead;
wherein the bulb is a glass bulb, and the glass bulb in a hot state is placed by its edge onto a support until the ring-shaped bead is formed.

11. A method for manufacturing a semiconductor lamp, the method comprising:
filling a receptacle space of a heat sink of the semiconductor lamp with a liquid or pasty filling compound;
dipping a diffuser into the filling compound;
curing the filling compound.
